(19) United States
(12) Patent Application Publication
(10) Pub. No.: US 2023/0307386 A1
(43) Pub. Date: Sep. 28, 2023

(54) BOUNDARY CELLS ADJACENT TO KEEP-OUT ZONES

(71) Applicants: TAIWAN SEMICONDUCTOR MANUFACTURING COMPANY, LTD., Hsinchu (TW); TSMC CHINA COMPANY, LIMITED, Shanghai (CN); TSMC NANJING COMPANY, LIMITED, Jiangsu (CN)

(72) Inventors: Jia Liang ZHONG, Hsinchu (TW); XinYong WANG, Hsinchu (TW); Cun Cun CHEN, Hsinchu (TW)

(21) Appl. No.: 17/721,246

(22) Filed: Apr. 14, 2022

(30) Foreign Application Priority Data
Mar. 22, 2022 (CN) 202210281459.8

(51) Int. Cl. H01L 23/60; H01L 23/48; H01L 27/02

(52) U.S. Cl. CPC H01L 23/60; H01L 23/481; H01L 27/0266

(57) ABSTRACT

An integrated circuit includes an array of first-type active-region structures and an array of second-type active-region structures extending in a first direction between a first vertical zone-boundary of a first keep-out zone and the second vertical zone-boundary of a second keep-out zone. The integrated circuit also includes an array of first-side boundary cells aligned with the first vertical zone-boundary and an array of second-side boundary cells aligned with the second vertical zone-boundary. In the array of first-side boundary cells, a first-side boundary cell has a first ESD protection circuit and a pick-up region. In the array of second-side boundary cells, a second-side boundary cell has a second ESD protection circuit.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic floor plan of an integrated circuit, in accordance with some embodiments.

FIGS. 2A-2E are schematic drawings of various device regions in the boundary cells which surrounds the keep-out zones in FIG. 1, in accordance with some embodiments.

FIGS. 3A-3B are schematic floor plans of an area between two vertical zone-boundaries of the keep-out zones, in accordance with some embodiments.

FIGS. 4A-4B are layout diagrams of a section of ESD device regions in the boundary cell in FIG. 3A, in accordance with some embodiments.

FIG. 4A1 is a cross-sectional view of the ESD device regions as specified by FIG. 4A in a cutting plane A-A′, in accordance with some embodiments.

FIG. 4A2 is a cross-sectional view of the ESD device regions as specified by FIG. 4A in a cutting plane B-B′, in accordance with some embodiments.

FIG. 4A3 is a cross-sectional view of the ESD device regions as specified by FIG. 4A in a cutting plane C-C′, in accordance with some embodiments.

FIG. 4C is a layout diagram of a section of the p-type pick-up region and the padding region in the boundary cell in FIG. 3B, in accordance with some embodiments.

FIG. 4D is a layout diagram of a section of the n-type pick-up region and the padding region in the boundary cell in FIG. 3B after flipped vertically, in accordance with some embodiments.

FIG. 4E is a layout diagram of a section of the padding regions in the boundary cell of FIG. 2D, in accordance with some embodiments.

FIGS. 5A-5B are the stick diagrams correspondingly represent the layout diagrams in FIGS. 4A-4B, in accordance with some embodiments.

FIGS. 5C-5D are the stick diagrams correspondingly represent the layout diagrams in FIGS. 4C-4D, in accordance with some embodiments.

FIG. 5E is the stick diagram representing the layout diagram in FIG. 4E, in accordance with some embodiments.

FIGS. 6A-6B are the equivalent circuits corresponding respectively to the stick diagrams of FIGS. 5A-5B.

FIGS. 6C-6D are the equivalent circuits corresponding respectively to the stick diagrams of FIGS. 5C-5D.

FIG. 6E is the equivalent circuit corresponding to the stick diagrams of FIG. 5E.

FIG. 7A is a schematic floor plan of an integrated circuit, in accordance with some embodiments.

FIGS. 7B-7C are examples of the boundary cells in the array boundary cells as shown in FIG. 7B.

FIGS. 8A-8B is a schematic floor plan of an area between two vertical zone-boundaries of the keep-out zones, in accordance with some embodiments.

FIG. 9 is a cross-sectional view of a semiconductor device, in accordance with some embodiments.

FIG. 10 is a block diagram of an electronic design automation (EDA) system in accordance with some embodiments.

FIG. 11 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an integrated circuit includes one or more rectangular keep-out zones, and each of the keep-out zone is designed to accommodate at least one through silicon via (“TSV”). In some integrated circuits, a conductive pillar passing through a TSV is implemented as part of an RF antenna. In some embodiments, boundary cells are implemented adjacent to keep-out zones and aligned with the zone-boundaries of keep-out zones. When some boundary cells are implemented with pick-up regions to maintain the proper voltage levels for the n-wells for the PMOS transistors and the p-wells for NMOS transistors, some areas between two adjacent rectangular keep-out zones are available for implementing functional circuit cells even if tap cells are not implemented in the areas between the two adjacent rectangular keep-out zones. Additionally, when some boundary cells are implemented with Electro Static Discharge (“ESD”) protection circuits for protecting the MOS transistors from electro static discharges, more areas between two adjacent rectangular keep-out zones are available for implementing functional circuit cells, as compared with alternative designs in which ESD protection circuits are also implemented in the areas between the two adjacent rectangular keep-out zones. Some ESD protection circuits include diode devices. Some ESD protection circuits include enlarged gate-conductor areas to protect the MOS transistors from electro static discharges resulting from antenna effects.

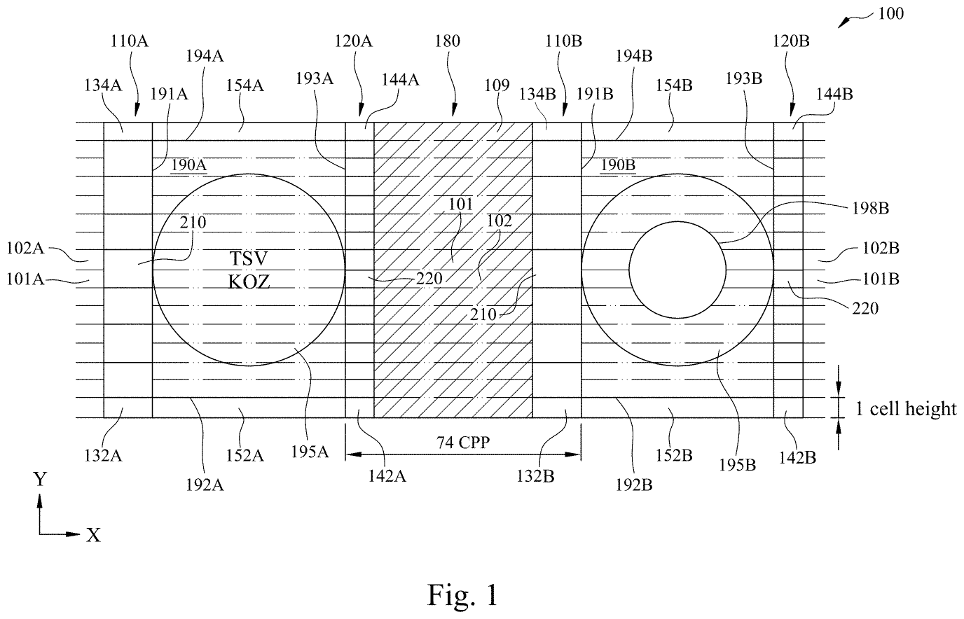

FIG. 1 is a schematic floor plan of an integrated circuit 100, in accordance with some embodiments. As shown in the floor plan, the integrated circuit 100 has two rectangular keep-out zones 190A and 190B. The keep-out zone 190A is bounded by two vertical zone-boundaries 191A and 193A and two horizontal zone-boundaries 192A and 194A. The keep-out zone 190B is bounded by two vertical zone-boundaries 191B and 193B and two horizontal zone-boundaries 192B and 194B. In some embodiments, each of the keep-out zones specifies an area (in the integrated circuit 100) which is devoid from circuit cells positioned by an Automatic Place and Route (APR) program. In some embodiments, each of the keep-out zones specifies an area (in the integrated circuit 100) which is devoid from circuit structures specified by cell designs fetched from a cell library or a cell database. In some embodiments, each of the keep-out zones specifies an area (in the integrated circuit 100) which does not contain transistors and/or pn junction diodes.

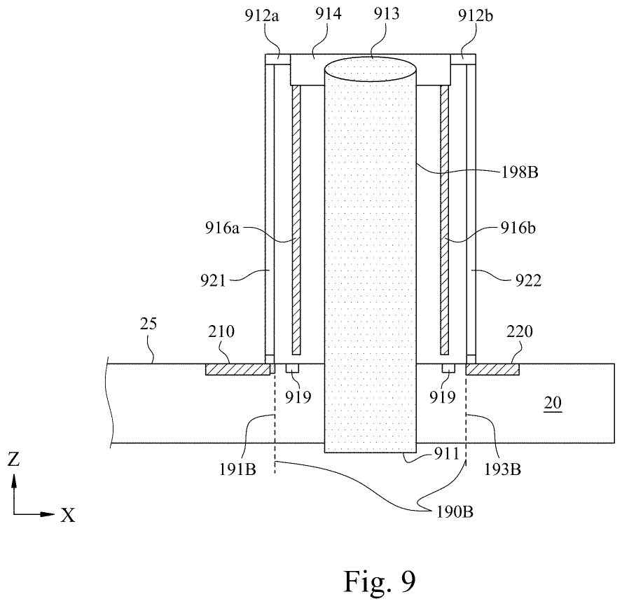

In the non-limiting example as shown in FIG. 1, each of the keep-out zones 190A and 190B includes an area reserved for implementing a through silicon via (TSV) 198B. Specifically, the keep-out zone 190A is designed to accommodate a circular TSV keep-out zone 195A for implementing a corresponding TSV at the center of the circular TSV keep-out zone 195A, and the keep-out zone 190B is designed to accommodate a TSV circular keep-out zone 195B for implementing a corresponding TSV at the center of the circular TSV keep-out zone 195B. A cross-sectional view of the TSV 198B is shown in FIG. 9.

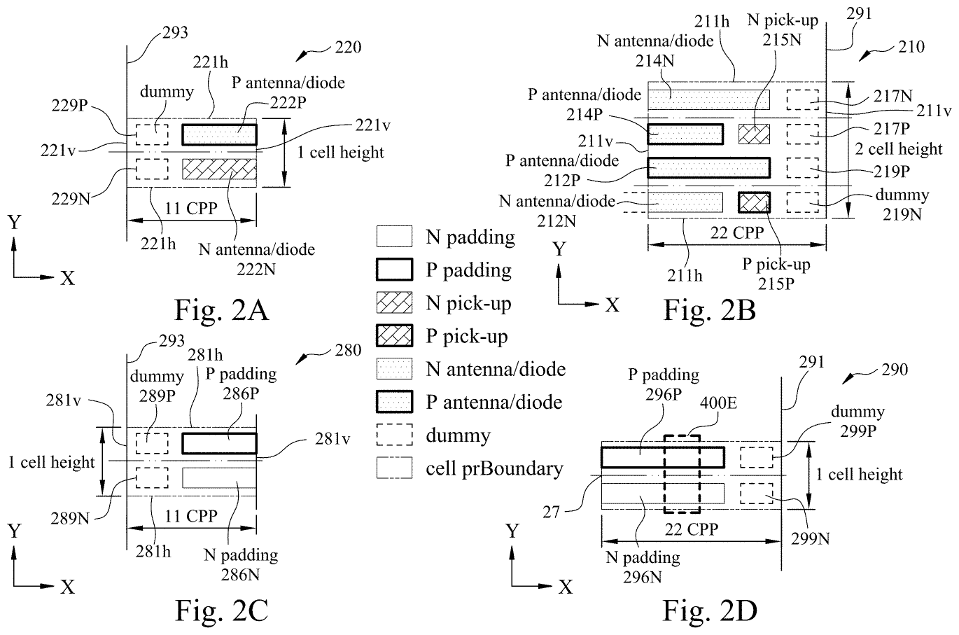

In FIG. 1, an array 110A of boundary cells is aligned along the Y-direction with the vertical zone-boundary 191A at the left side of the keep-out zone 190A, and an array 110B of boundary cells is aligned along the Y-direction with the vertical zone-boundary 191B at the left side of the keep-out zone 190B. An example of the boundary cells in the array 110A and 110B is shown in FIG. 2B as a boundary cell 210. In FIG. 1, an array 120A of boundary cells is aligned along the Y-direction with the vertical zone-boundary 193A at the right side of the keep-out zone 190A, and an array 120B of boundary cells is aligned along the Y-direction with the vertical zone-boundary 193B at the right side of the keep-out zone 190B. An example of the boundary cells in the array 120A and 120B is shown in FIG. 2A as a boundary cell 220.

FIGS. 2A-2E are schematic drawings of various device regions in the boundary cells which surround the keep-out zones in FIG. 1, in accordance with some embodiments. The boundary cell 220 in FIG. 2A is implemented as the boundary cell for use in the arrays 120A and 120B of the boundary cells at the right side of the keep-out zones. The boundary cell 220 has two horizontal boundaries 221h extending in the X-direction and two vertical boundaries 221v extending in the Y-direction. The Y-direction is perpendicular to the X-direction. One of the vertical cell boundaries 221v of the boundary cell 220 is aligned with a vertical zone-boundary 293 of a keep-out zone. As examples, when the boundary cell 220 is used in the array 120A of boundary cells at the right side of the keep-out zone 190A in FIG. 1, one of the vertical cell boundaries of the boundary cell 220 is aligned with the vertical zone-boundary 193A. When the boundary cell 220 is used in the array 120B of boundary cells at the right side of the keep-out zone 190B in FIG. 1, one of the vertical cell boundaries of the boundary cell 220 is aligned with the vertical zone-boundary 193B.

In some embodiments, the vertical cell boundary of the boundary cell 220 is in alignment with the vertical zone-boundary 293 such that the vertical cell boundary directly meets the vertical zone-boundary 293. In some embodiments, the vertical cell boundary of the boundary cell 220 is sufficiently aligned with the vertical zone-boundary 293 such that the distance separating the vertical cell boundary 221v and the vertical zone-boundary 293 along the X-direction is deemed acceptable by designers who are people of ordinary skill in the art.

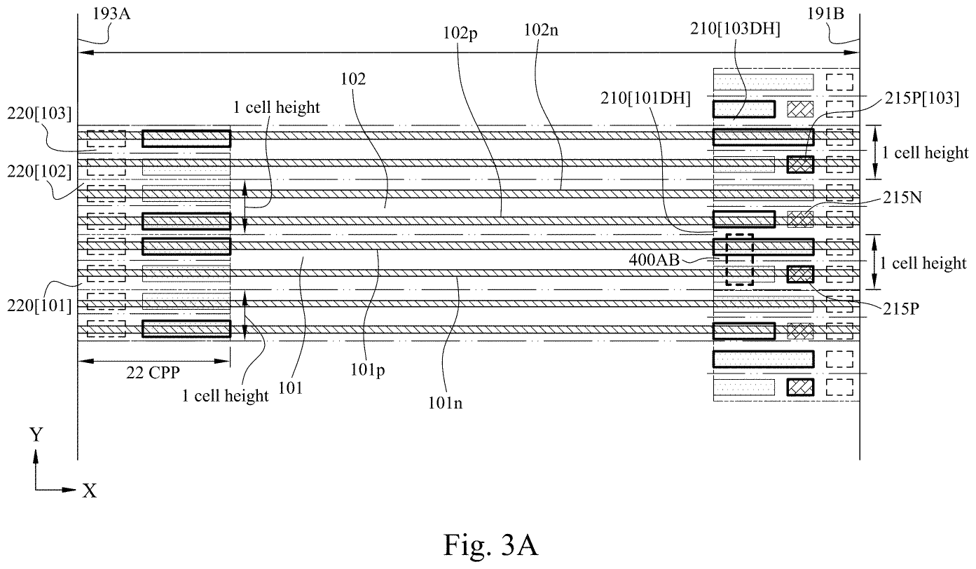

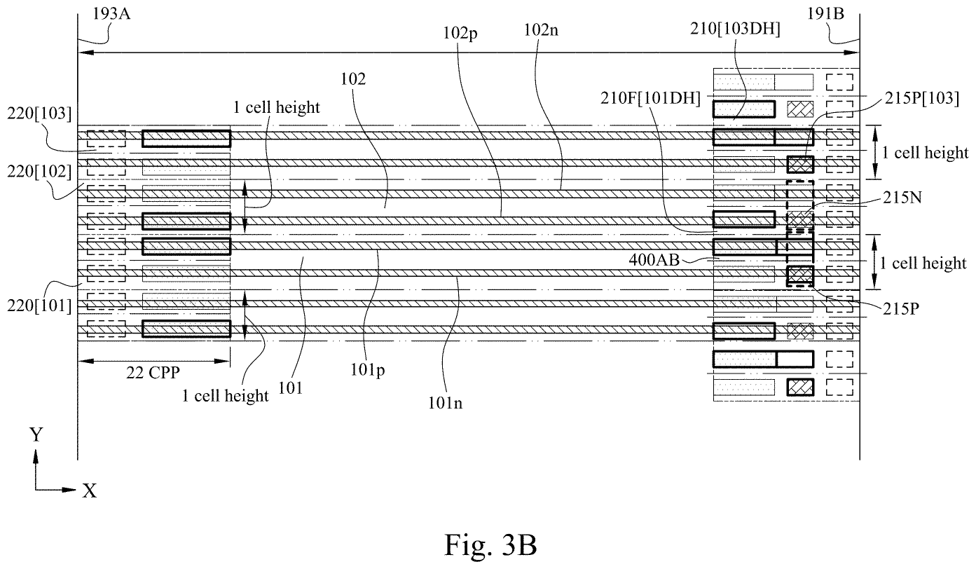

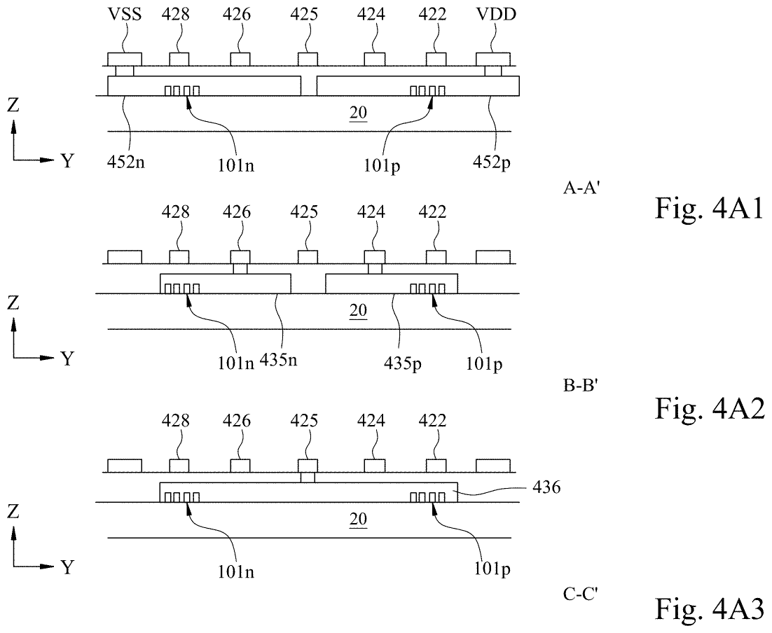

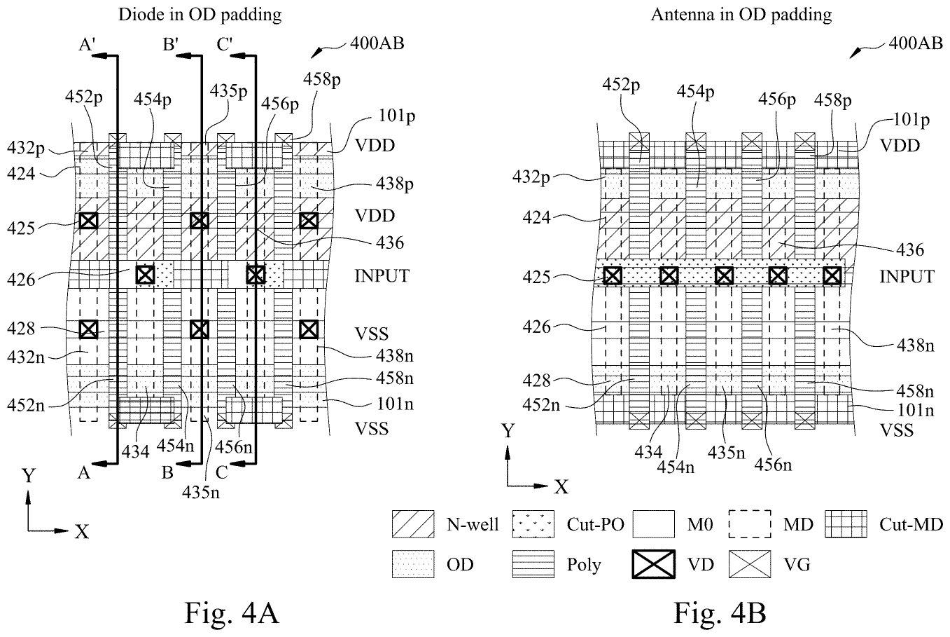

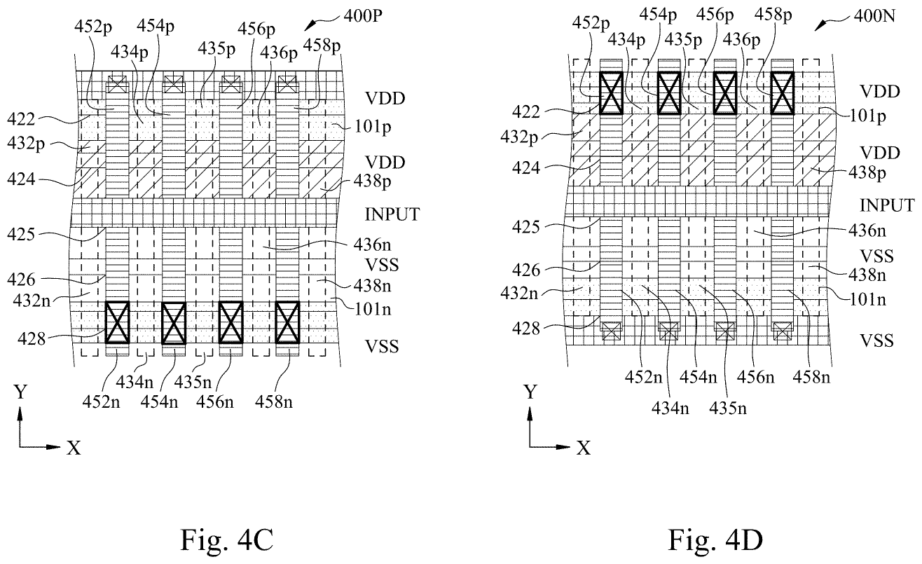

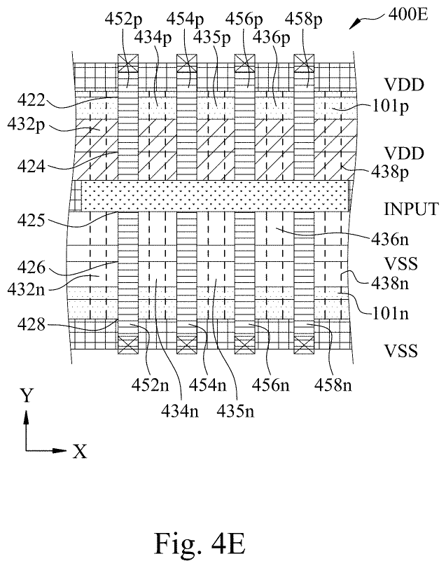

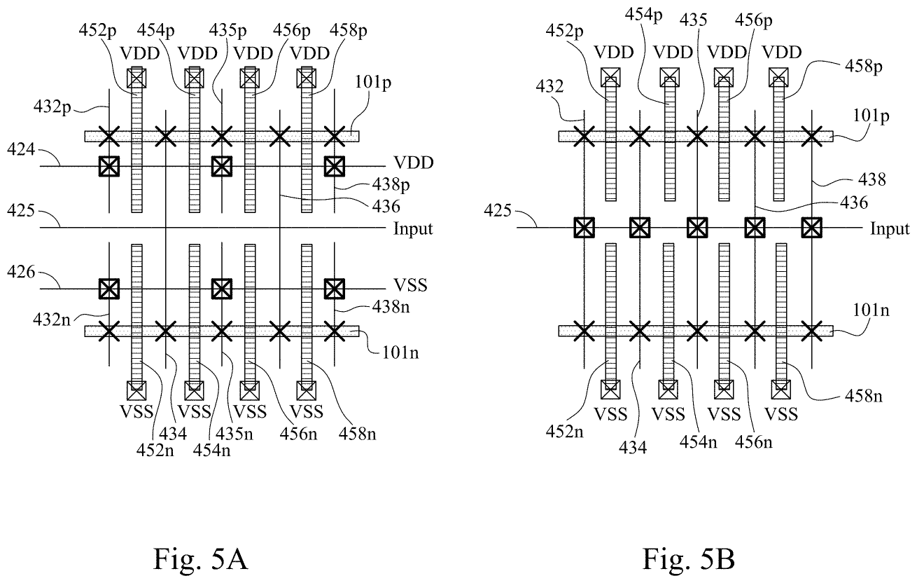

In FIG. 2A, the boundary cell 220 includes a p-type ESD device region 222P and a dummy device region 229P in an active-region structure 101p extending in the X-direction. The active-region structure 101p has one or more channel regions and source/drain regions of PMOS transistors. The dummy device region 229P has a width sufficiently large along the X-direction to satisfy design rule requirements. The dummy device region 229P is between the p-type ESD device region 222P and the vertical zone-boundary 293. The boundary cell 220 also includes an n-type ESD device region 222N and a dummy device region 229N in an active-region structure 101n extending in the X-direction. The active-region structure 101n has one or more channel regions and source/drain regions of NMOS transistors. The dummy device region 229N has a width sufficiently large along the X-direction to satisfy design rule requirements. The dummy device region 229N is between the n-type ESD device region 222N and the vertical zone-boundary 293. Sections of example designs of the boundary cell 220 having the p-type ESD device region 222P and the n-type ESD device region 229N are depicted in FIGS. 4A-4B. In some embodiments, the length of the p-type ESD device region 222P along the X-direction occupies most of the length of the active-region structure 101p within the boundary cell 220. In some embodiments, the length of the n-type ESD device region 222N along the X-direction occupies most of the length of the active-region structure 101p within the boundary cell 220.

In FIG. 2B, the boundary cell 210 is implemented as the boundary cell for use in the arrays 110A and 110B of the boundary cells at the left side of the keep-out zones. The boundary cell 210 has two horizontal boundaries 211h extending in the X-direction and two vertical boundaries 211v extending in the Y-direction. One of the vertical cell boundaries of the boundary cell 210 is aligned with a vertical zone-boundary 291 of a keep-out zone. As examples, when the boundary cell 210 is used in the array 110A of boundary cells at the left side of the keep-out zone 190A in FIG. 1, one of the vertical cell boundaries of the boundary cell 210 is aligned with the vertical zone-boundary 191A. When the boundary cell 210 is used in the array 110B of boundary cells at the left side of the keep-out zone 190B in FIG. 1, one of the vertical cell boundaries of the boundary cell 210 is aligned with the vertical zone-boundary 191B.

In some embodiments, the vertical cell boundary of the boundary cell 210 is in alignment with the vertical zone-boundary 291 such that the vertical cell boundary directly meets the vertical zone-boundary 291. In some embodiments, the vertical cell boundary of the boundary cell 210 is sufficiently aligned with the vertical zone-boundary 291 such that the distance separating the vertical cell boundary and the vertical zone-boundary 291 along the X-direction is deemed acceptable by designers who are people of ordinary skill in the art.

In FIG. 2B, the boundary cell 210 includes a p-type ESD device region 212P and a dummy device region 219P in an active-region structure 101p extending in the X-direction, and the boundary cell 210 also includes a p-type ESD device region 214P and a dummy device region 217P in an active-region structure 102p extending in the X-direction. Each of the active-region structures 101p and 102p has one or more channel regions and source/drain regions of PMOS transistors. An n-type pick-up region 215N is implemented between two segments of the active-region structure 102p. A section of an example design of the n-type pick-up region 215N is depicted in FIG. 4E. Each of the dummy device regions 219P and 217P has a width sufficiently large along the X-direction to satisfy design rule requirements. The dummy device region 219P is between the p-type ESD device region 212P and the vertical zone-boundary 291. The dummy device region 217P is between the n-type pick-up region 215N and the vertical zone-boundary 291. The n-type pick-up region 215N is between the p-type ESD device region 214P and the dummy device region 217P.

In FIG. 2B, the boundary cell 210 includes an n-type ESD device region 212N and a dummy device region 219N in an active-region structure 101n extending in the X-direction, and the boundary cell 210 also includes an n-type ESD device region 214N and a dummy device region 217N in an active-region structure 102n extending in the X-direction. Each of the active-region structures 101n and 102n has one or more channel regions and source/drain regions of NMOS transistors. A p-type pick-up region 215P is implemented between two segments of the active-region structure 101n. A section of an example design of the p-type pick-up region 215P is depicted in FIG. 4D. Each of the dummy device regions 219N and 217N has a width sufficiently large along the X-direction to satisfy design rule requirements. The dummy device region 217N is between the n-type ESD device region 214N and the vertical zone-boundary 291. The dummy device region 219N is between the p-type pick-up region 215P and the vertical zone-boundary 291. The p-type pick-up region 215P is between the n-type ESD device region 212N and the dummy device region 219N.

The corner cell 280 in FIG. 2C is implemented for use at the corners of the keep-out zones. One of the vertical cell boundaries of the corner cell 280 is aligned with a vertical zone-boundary 293 of a keep-out zone. As examples, when the corner cell 280 is used as the corner cells 142A and 144A at the corners of the keep-out zone 190A in FIG. 1, one of the vertical cell boundaries of the corner cell 280 is aligned with the vertical zone-boundary 193A. When the corner cell 280 is used as the corner cells 142B and 144B at the corners of the keep-out zone 190B in FIG. 1, one of the vertical cell boundaries of the corner cell 280 is aligned with the vertical zone-boundary 193B.

In FIG. 2C, the corner cell 280 includes a p-type padding region 286P and a dummy device region 289P in an active-region structure 109p extending in the X-direction. The dummy device region 289P has a width sufficiently large along the X-direction to satisfy design rule requirements. The dummy device region 289P is between the p-type padding region 286P and the vertical zone-boundary 293. In FIG. 2C, the corner cell 280 also includes an n-type padding region 286N and a dummy device region 289N in an active-region structure 109n extending in the X-direction. The dummy device region 289N has a width sufficiently large along the X-direction to satisfy design rule requirements. The dummy device region 289N is between the n-type padding region 286N and the vertical zone-boundary 293. A section of an example design of a p-type padding region and an n-type padding region are depicted in FIG. 4C.

The corner cell 290 in FIG. 2D is implemented for use at the corners of the keep-out zones. One of the vertical cell boundaries of the corner cell 290 is aligned with a vertical zone-boundary 291 of a keep-out zone. As examples, when the corner cell 290 is used as the corner cells 132A and 134A at the corners of the keep-out zone 190A in FIG. 1, one of the vertical cell boundaries of the corner cell 290 is aligned with the vertical zone-boundary 191A. When the corner cell 290 is used as the corner cells 132B and 134B at the corners of the keep-out zone 190B in FIG. 1, one of the vertical cell boundaries of the corner cell 290 is aligned with the vertical zone-boundary 191B.

In FIG. 2D, the corner cell 290 includes a p-type padding region 296P and a dummy device region 299P in an active-region structure 109p extending in the X-direction. The dummy device region 299P has a width sufficiently large along the X-direction to satisfy design rule requirements. The dummy device region 299P is between the p-type padding region 296P and the vertical zone-boundary 291. In FIG. 2D, the corner cell 290 also includes an n-type padding region 296N and a dummy device region 299N in an active-region structure 109n extending in the X-direction. The dummy device region 279N has a width sufficiently large along the X-direction to satisfy design rule requirements. The dummy device region 299N is between the n-type padding region 296N and the vertical zone-boundary 291. A section of an example design of a p-type padding region and an n-type padding region is depicted in FIG. 4C.

In FIG. 1, in addition to the corner cells (132A, 134A, 142A, and 144A) at the corners of the keep-out zone 190A and the corner cells (132B, 134B, 142B, and 144B) at the corners of the keep-out zone 190B, other areas in the floor plan of FIG. 1 also include padding regions in accordance some embodiments. For example, in some embodiments, one or more of the areas 152A, 154A, 152B, and 154B adjacent to the horizontal zone-boundaries of the keep-out zones also include p-type padding regions and n-type padding regions. Here, the areas 152A and 154A are correspondingly adjacent to the horizontal zone-boundaries 192A and 194A. The areas 152B and 154B are correspondingly adjacent to the horizontal zone-boundaries 192B and 194B.

In the floor plan of FIG. 1, an area between the vertical zone-boundaries 193A and 191B is implemented with an array 120A of boundary cells adjacent to the vertical zone-boundary 193A and an array 110B of boundary cells adjacent to the vertical zone-boundary 191B. Multiple rows of circuit cells (e.g., the cell row 101 and the cell row 102) are implemented in the area 180 between the array 120A of boundary cells and the array 110B of boundary cells. In some embodiments, adjacent cell rows in the area 180 are grouped into pairs of cell rows, and each pair of cell rows is terminated with a double height boundary cell (e.g., the boundary 210 in FIG. 2B) at one end and two single height boundary cells (e.g., the boundary 220 in FIG. 2A) at the other end.

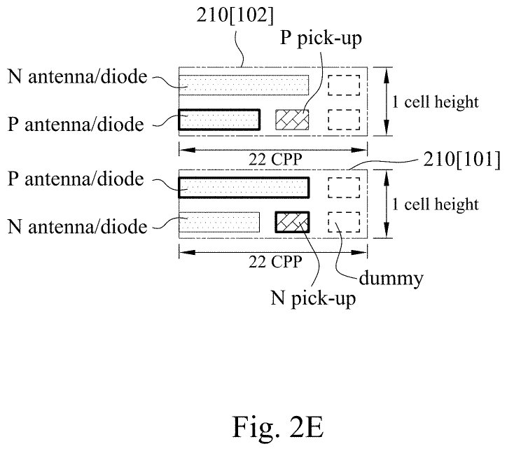

FIGS. 3A-3B are schematic floor plans of an area between two vertical zone-boundaries of the keep-out zones, in accordance with some embodiments. The cell rows 101 and 102 are terminated with a boundary cell 210[101DH] adjacent to the vertical zone-boundary 191B and terminated with two boundary cells 220[101] and 220[102] adjacent to the vertical zone-boundary 193A. An example implementation of the boundary cell 220[101] or 220[102] is described with respect to the boundary cell 220 in FIG. 2A. An example implementation of the boundary cell 210[101DH] in FIG. 3A is described with respect to the boundary cell 210 in FIG. 2B. In some alternative embodiments, the boundary cell 210[101DH] in FIG. 3A is substituted with two boundary cells 210[101] and 210[102] in FIG. 2E. In still some alternative embodiments, the boundary cell 210[101DH] in FIG. 3A is substituted with the boundary cell 210[101DH] in FIG. 3B having padding regions 216P and 216N. The padding region 216P is aligned with the ESD device region 214P in the active-region structures 101p. The padding region 216N is aligned with the ESD device region 214N in the active-region structures 101n.

In FIGS. 3A-3B, the cell row 101 includes active-region structures 101p and 101n extending in the X-direction between the vertical zone-boundaries 193A and 191B. The active-region structures 101p and 101n form a pair of adjacent active-region structures in the cell row 101. The cell row 102 includes active-region structures 102p and 102n extending in the X-direction between the vertical zone-boundaries 193A and 191B. The active-region structures 102p and 102n form a pair of adjacent active-region structures in the cell row 102. Each of the active-region structures 101p and 102p includes one or more channel regions and source/drain regions of PMOS transistors. Each of the active-region structures 101n and 102n includes one or more channel regions and source/drain regions of PMOS transistors.

In addition, each of the active-region structures 101p, 101n, 102p, and 102n also includes isolation structures, whereby the channel regions and source/drain regions in a circuit cell are isolated from the channel regions and source/drain regions in its neighbor circuit cells. In some embodiments, the vertical boundaries of a circuit cell in a cell row (e.g., 101) are identifiable in an integrated circuit device by identifying the isolation structures in the corresponding active-region structures (e.g., 101p and 101n) in the cell row. In some embodiments, the horizontal boundaries of a circuit cell in a cell row (e.g., 101) are identifiable in an integrated circuit device by identifying the power rails shared with its neighbor cell rows (e.g., 102 or 103). In some embodiments, an active-region structure (e.g., 101p) for PMOS transistors are identifiable in an integrated circuit device by identifying the alignment of the source/drain regions of the PMOS transistors in the corresponding cell row (e.g., 101), and an active-region structure (e.g., 101n) for NMOS transistors are identifiable in an integrated circuit device by identifying the alignment of the source/drain regions of the NMOS transistors in the corresponding cell row (e.g., 101).

In FIGS. 3A-3B, the n-type well surrounding the active-region structures 101p and 102p for PMOS transistors is configured to be maintained at the upper supply voltage VDD with the tap cells in the n-type pick-up region 215N. The p-type well surrounding the active-region structures 101n for NMOS transistor is configured to be maintained at the lower supply voltage VSS with the tap cells in the p-type pick-up region 215P. The p-type well surrounding the active-region structures 102n for NMOS transistor is configured to be maintained at the lower supply voltage VSS with the tap cells in the p-type pick-up region 215P[103] in the boundary cell 210[103DH] which is adjacent to the boundary cell 210[101DH]. In FIGS. 3A-3B, the cell row 103 is terminated with the boundary cell 210[103DH] adjacent to the vertical zone-boundary 191B and terminated with the boundary cell 220[103] adjacent to the vertical zone-boundary 193A.

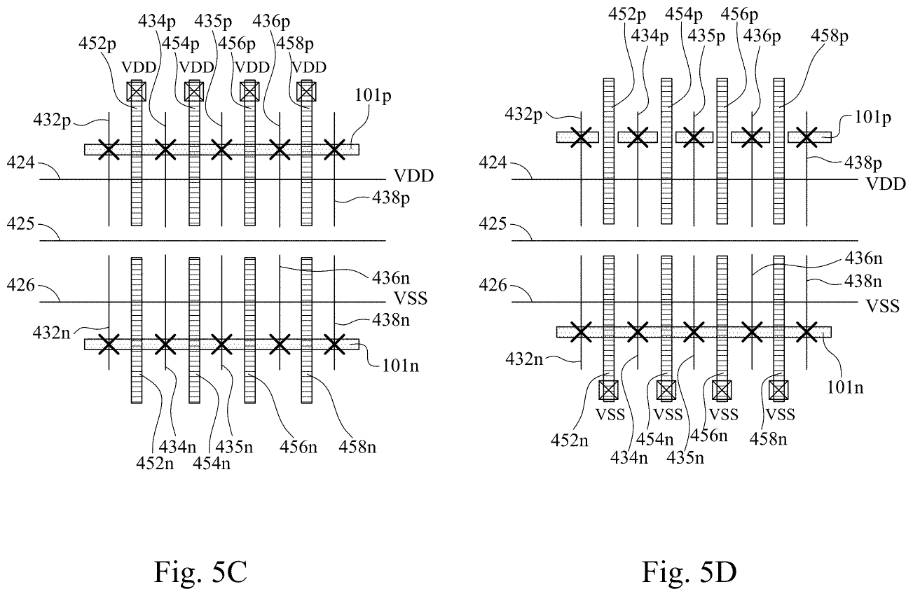

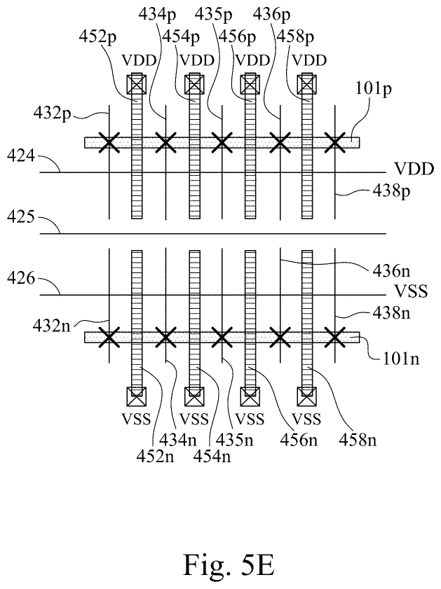

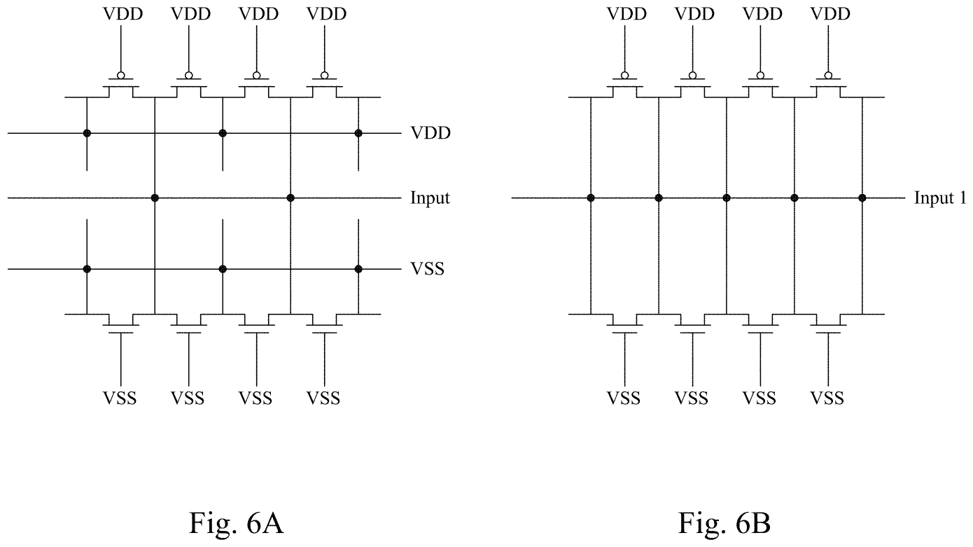

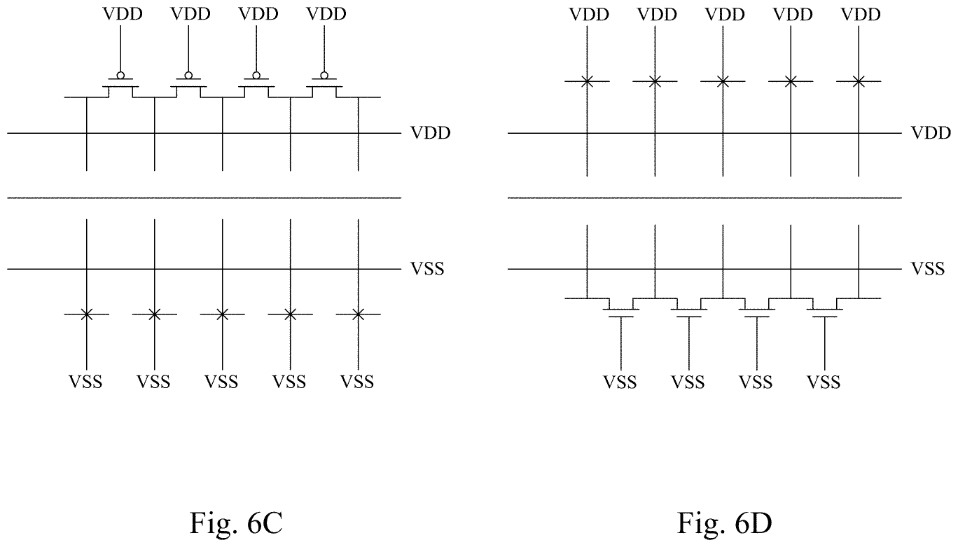

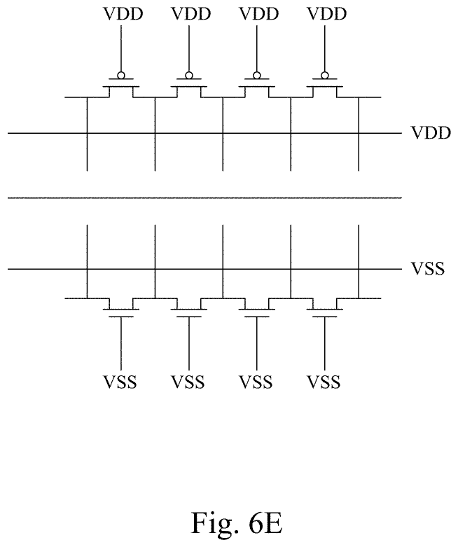

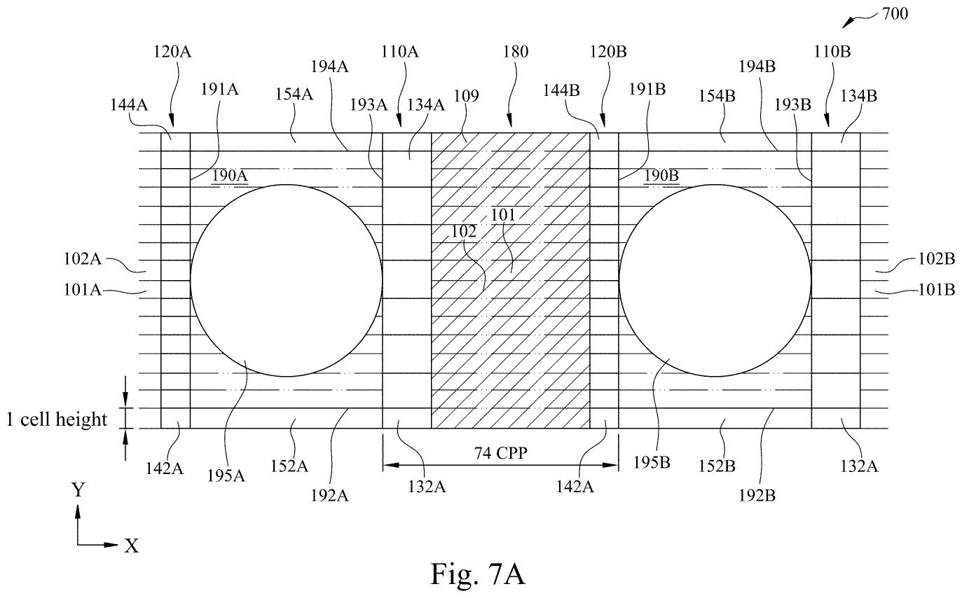

FIGS. 4A-4B are layout diagrams of a section 400AB of ESD device regions 212P and 212N in the boundary cell 210[101DH] in FIG. 3A, in accordance with some embodiments. FIGS. 5A-5B are stick diagrams correspondingly representing the layout diagrams in FIGS. 4A-4B, in accordance with some embodiments. FIGS. 6A-6B are equivalent circuits corresponding respectively to the stick diagrams of FIGS. 5A-5B. As shown in FIGS. 4A-4B and FIGS. 5A-5B, each of the layout diagrams of FIGS. 4A-4B includes the layout patterns for specifying the active-region structures 101p and 101n extending in the X-direction, and the horizontal conducting lines 422, 424, 425, 426, and 428 extending in the X-direction. Each of the layout diagrams of FIGS. 4A-4B includes the layout patterns for specifying the gate-conductors extending in the Y-direction, and the terminal-conductors extending in the Y-direction. The gate-conductors as specified by the layout patterns in FIGS. 4A-4B include gate-conductors 452p, 452n, 454p, 454n, 456p, 456n, 458p, and 458n. Each of the gate-conductors 452p, 454p, 456p, and 458p intersects the active-region structure 101p and functions as the gate terminal of a PMOS transistor in the ESD device region 212P. Each of the gate-conductors 452n, 454n, 456n, and 458n intersects the active-region structure 101n and functions as the gate terminal of an NMOS transistor in the ESD device region 212N. Furthermore, each of the gate-conductors 452p, 454p, 456p, and 458p is connected to the upper supply voltage VDD through a corresponding via connector VG, and each of the gate-conductors 452n, 454n, 456n, and 458n is connected to the lower supply voltage VSS through a corresponding via connector VG.

As shown in FIG. 4A and FIG. 5A, the terminal-conductors as specified by the layout patterns in FIG. 4A include the terminal-conductors 432p, 432n, 434, 435p, 435n, 436, 438p, and 438n. Each of the terminal-conductors 432p, 435p, and 438p is connected to the horizontal conducting line 424 through a corresponding via connector VD, and the horizontal conducting line 424 is maintained at the upper supply voltage VDD. Each of the terminal-conductors 432n, 435n, and 438n is connected to the horizontal conducting line 426 through a corresponding via connector VD, and the horizontal conducting line 426 is maintained at the lower supply voltage VSS. Additionally, each of the terminal-conductors 434 and 436 is connected to the horizontal conducting line 425 through a corresponding via connector VD, and the horizontal conducting line 425 functions as an input node of an ESD protection circuit. The equivalent circuit corresponding to the layout patterns in FIG. 4A is shown in FIG. 6A. Each of the ESD device regions 212P and 212N in FIG. 4A is a diode device region.

As shown in FIG. 4B and FIG. 5B, the terminal-conductors as specified by the layout patterns in FIG. 4B include the terminal-conductors 432, 434, 435, 436, and 438. Each of the terminal-conductors 432, 434, 435, 436, and 438 is connected to the horizontal conducting line 425 through a corresponding via connector VD, and the horizontal conducting line 425 functions as an input node of an antenna effect protection circuit. The equivalent circuit corresponding to the layout patterns in FIG. 4B is shown in FIG. 6B. Each of the ESD device regions 212P and 212N in FIG. 4B is an antenna device region.

FIG. 4A1 is a cross-sectional view of the ESD device regions 212P and 212N as specified by FIG. 4A in a cutting plane A-A′, in accordance with some embodiments. In FIG. 4A1, the gate-conductor 452p intersects the active-region structure 101p on the substrate 20, and the gate-conductor 452n intersects the active-region structure 101n on the substrate 20. The horizontal conducting lines 422, 424, 425, 426, and 428 are in the first metal layer overlying the insulation layer which covers the gate-conductors 452p and 452n. The gate-conductors 452p and 452n are correspondingly connected to the power rails VDD and VSS through a via connector VG.

FIG. 4A2 is a cross-sectional view of the ESD device regions 212P and 212N as specified by FIG. 4A in a cutting plane B-B′, in accordance with some embodiments. In FIG. 4A2, the terminal-conductor 435p intersects the active-region structure 101p on the substrate 20, and the terminal-conductor 435n intersects the active-region structure 101n on the substrate 20. The horizontal conducting lines 422, 424, 425, 426, and 428 are in the first metal layer overlying the insulation layer which covers the terminal-conductors 435p and 435n. The terminal-conductors 435p and 435n are correspondingly connected to the horizontal conducting lines 424 and 426 through a via connector VD.

FIG. 4A3 is a cross-sectional view of the ESD device regions 212P and 212N as specified by FIG. 4A in a cutting plane C-C′, in accordance with some embodiments. In FIG. 4A3, the terminal-conductor 436 intersects both the active-region structure 101p and the active-region structure 101n on the substrate 20. The horizontal conducting lines 422, 424, 425, 426, and 428 are in the first metal layer overlying the insulation layer which covers the terminal-conductor 436. The terminal-conductor 436 is connected to the horizontal conducting line 425 through a via connector VD.

FIG. 4C is a layout diagram of a section 400P of the p-type pick-up region 215P and the padding region 216P in the boundary cell 210[101DH] in FIG. 3B, in accordance with some embodiments. FIG. 4D is a layout diagram of a section 400N of the n-type pick-up region 215N and the padding region 216N in the boundary cell 210[101DH] in FIG. 3B after flipped vertically, in accordance with some embodiments. FIGS. 5C-5D are stick diagrams corresponding to the layout diagrams in FIGS. 4C-4D, in accordance with some embodiments. FIGS. 6C-6D are the equivalent circuits corresponding to the stick diagrams of FIGS. 5C-5D.

As shown in FIGS. 4C-4D and FIGS. 5C-5D, each of the layout diagrams of FIGS. 4C-4D includes the layout patterns for specifying the active-region structures 101p and 101n extending in the X-direction, and the horizontal conducting lines 422, 424, 425, 426, and 428 extending in the X-direction. Each of the layout diagrams of FIGS. 4C-4D includes the layout patterns for specifying the gate-conductors, the dummy gate conductors, and the terminal-conductors.

As shown in FIG. 4C and FIG. 5C, each of the gate-conductors 452p, 454p, 456p, and 458p intersects the active-region structure 101p and functions as the gate terminal of a PMOS transistor in the padding region 216P. Each of the gate-conductors 452p, 454p, 456p, and 458p is connected to the upper supply voltage VDD through a corresponding via connector VG. Each of the dummy gate-conductors 452n, 454n, 456n, and 458n intersects the active-region structure 101n at an isolation region. Each of the terminal-conductors 432n, 434n, 435n, 436n, and 438n is connected to a lower supply voltage VSS through a corresponding via connector (not show in FIG. 4C), whereby the p-type well surrounding the active-region structures 102n is maintained at the lower supply voltage VSS. The equivalent circuit corresponding to the layout patterns in FIG. 4C is shown in FIG. 6C.

As shown in FIG. 4D and FIG. 5D, each of the gate-conductors 452n, 454n, 456n, and 458n intersects the active-region structure 101n and functions as the gate terminal of a NMOS transistor in the padding region 216N. Each of the gate-conductors 452n, 454n, 456n, and 458n is connected to the lower supply voltage VSS through a corresponding via connector VG. Each of the dummy gate-conductors 452p, 454p, 456p, and 458p intersects the active-region structure 101p at an isolation region. Each of the terminal-conductors 432p, 434p, 435p, 436p, and 438p is connected to an upper supply voltage VDD through a corresponding via connector (not shown in FIG. 4D), whereby the n-type well surrounding the active-region structures 102p is maintained at the upper supply voltage VDD. The equivalent circuit corresponding to the layout patterns in FIG. 4D is shown in FIG. 6D.

FIG. 4E is a layout diagram of a section 400E of the padding regions 276P and 276E in the boundary cell 290 of FIG. 2D, in accordance with some embodiments. FIG. 5E is a stick diagram representing the layout diagram in FIG. 4E, in accordance with some embodiments. FIG. 6E is an equivalent circuit corresponding to the stick diagram of FIG. 5E. As shown in FIG. 4E and FIG. 5E, the layout diagram of FIG. 4E includes the layout patterns for specifying the active-region structures 101p and 101n and the layout patterns for specifying the horizontal conducting lines 422, 424, 425, 426, and 428 extending in the X-direction. The layout diagram of FIG. 4E includes the layout patterns for specifying the gate-conductors and the terminal-conductors. The terminal-conductors as specified by the layout patterns in FIG. 4E include the terminal-conductors 432p, 432n, 434p, 434n, 435p, 435n, 436p, 436n, 438p, and 438n. In FIG. 4E and FIG. 5E, each of the gate-conductors 452p, 454p, 456p, and 458p intersects the active-region structure 101p and connects to the upper supply voltage VDD through a corresponding via connector VG. Each of the gate-conductors 452n, 454n, 456n, and 458n intersects the active-region structure 101n and connects to the lower supply voltage VSS through a corresponding via connector VG. The equivalent circuit corresponding to the layout patterns in FIG. 4E is shown in FIG. 6E.

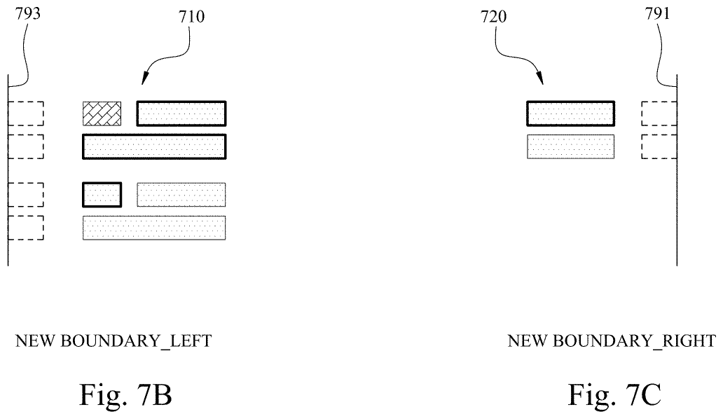

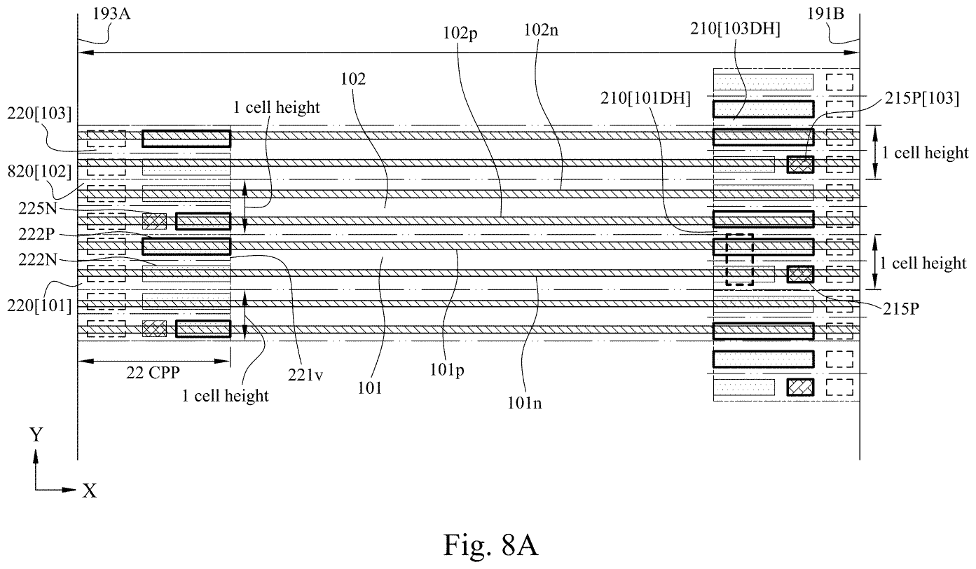

FIG. 7A is a schematic floor plan of an integrated circuit 700, in accordance with some embodiments. The floor plan in FIG. 7A is a modification of the floor plan in FIG. 1. In FIG. 7A, the array 110A of boundary cells is aligned along the Y-direction with the vertical zone-boundary 193A at the right side of the keep-out zone 190A, and the array 110B of boundary cells is aligned along the Y-direction with the vertical zone-boundary 193B at the right side of the keep-out zone 190B. As a comparison, in FIG. 1, the array 110A of boundary cells is aligned along the Y-direction with the vertical zone-boundary 191A at the left side of the keep-out zone 190A, and the array 110B of boundary cells is aligned along the Y-direction with the vertical zone-boundary 191B at the left side of the keep-out zone 190B. An example of the boundary cells in the array 110A and 110B is shown in FIG. 7B as a boundary cell 710.

Additionally in FIG. 1, an array 120A of boundary cells is aligned along the Y-direction with the vertical zone-boundary 191A at the left side of the keep-out zone 190A, and an array 120B of boundary cells is aligned along the Y-direction with the vertical zone-boundary 191B at the left side of the keep-out zone 190B. As a comparison, in FIG. 1 the array 120A of boundary cells is aligned along the Y-direction with the vertical zone-boundary 193A at the right side of the keep-out zone 190A, and the array 120B of boundary cells is aligned along the Y-direction with the vertical zone-boundary 193B at the right side of the keep-out zone 190B. An example of the boundary cells in the array 120A and 120B is shown in FIG. 7C as a boundary cell 720.

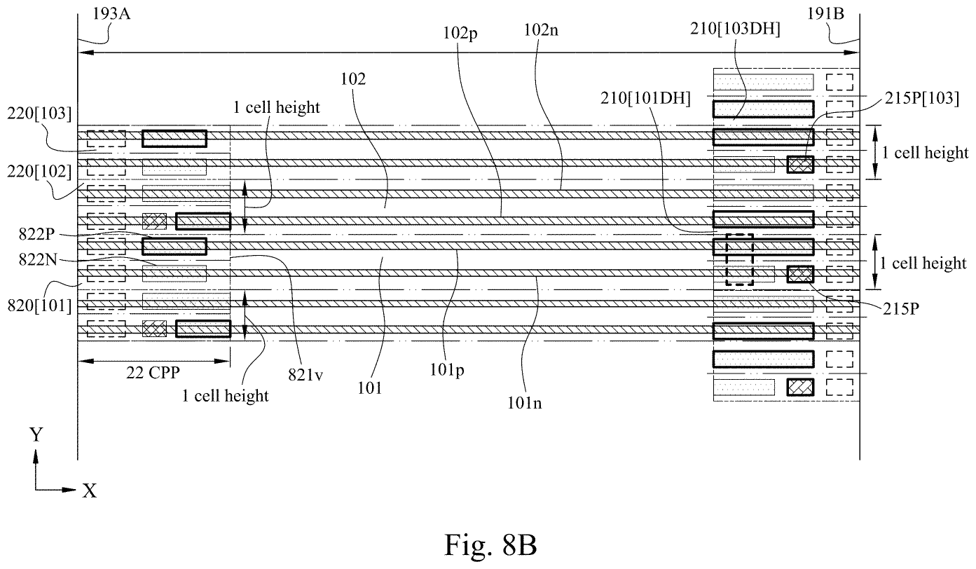

FIGS. 8A-8B is a schematic floor plan of an area between two vertical zone-boundaries of the keep-out zones, in accordance with some embodiments. The floor plan in FIG. 8A is a modification of the floor plan in FIG. 3A. In FIG. 8A, the n-type well surrounding the active-region structures 101p and 102p for PMOS transistors is configured to be maintained at the upper supply voltage VDD with the tap cells in the n-type pick-up region 815N in the boundary cell 820[102] adjacent to the vertical zone-boundary 193A. In contrast, in FIG. 3A the n-type well surrounding the active-region structures 101p and 102p for PMOS transistors is configured to be maintained at the upper supply voltage VDD with the tap cells in the n-type pick-up region 215N in the boundary cell 210 [101DH] adjacent to the vertical zone-boundary 191B.

The floor plan in FIG. 8B is a modification of the floor plan in FIG. 8A. In FIG. 8A, an edge of each of the ESD device regions 222P and 222N is aligned with one of the vertical boundaries 221v of the boundary cell 220[101]. In FIG. 8B, as a modification of FIG. 8A, edges of the ESD device regions 822P and 822N are not aligned with the vertical boundaries 821v of the boundary cell 820[101].

FIG. 9 is a cross-sectional view of a semiconductor device 900, in accordance with some embodiments. In the cross-sectional view of semiconductor device 900, the TSV 198B extends above top surface 25 of substrate 20. In semiconductor device 900, the first end 911 of TSV 198B is at a side of substrate 20 opposite from the boundary cells 210 and 220, and the second end 913 of TSV 198B is at the same side of the substrate 20 as the boundary cell 210 and 220. Circuit elements are excluded from the top surface 25 of the substrate 20 in the rectangular keep-out zone 190B between the vertical zone-boundaries 191B and 193B. In some embodiments, the exclusion extends upward along the sides of the TSV to the antenna pad 914. A ground ring 919 is between the boundary cells 210 and 220 at the top surface 25 of the substrate and the sidewalls of the TSV 198B. In some embodiments, the ground ring 919 extends deeper into the substrate than the boundary cells 210 and 220.

An antenna pad 914 is proximal to second end 913 of TSV 198B. In semiconductor device 900, antenna pad 914 is in direct contact with second end 913 of TSV 198B. In some embodiments, the antenna pad 914 is separated from the second end 913 of a TSV 911 by a layer of dielectric material, and electrically connects to the TSV by at least one contact or via extending from the antenna pad 914 to the second end 913 of the TSV 198B.

Antenna pad 914 electrically connects to the ESD protection circuits in the ESD cell boundary cells 210 and 220 in substrate 20 by conductive pillars 921 and 922, respectively. Conductive pillar 921 electrically connects to the ESD protection circuits in the boundary cell 210 and conductive line 912a. In some embodiments, the conductive pillar 921 electrically connects to the input node (e.g., the horizontal conducting line 425 in FIG. 4A and FIG. 5A) of the ESD protection circuit in the boundary cell 210. Conductive pillar 922 electrically connects to the ESD protection circuits in the boundary cell 220 and to conductive line 912b. In some embodiments, the conductive pillar 922 electrically connects to the input node (e.g., the horizontal conducting line 425 in FIG. 4A and FIG. 5A) of the ESD protection circuit in the boundary cell 220. Conductive line 912a and conductive line 912b electrically connect to antenna pad 914. In some embodiments, conductive lines electrically connect directly to an antenna pad 914.

In semiconductor device 900, antennas parts 916a and 916b extend from antenna pad 914 toward substrate 20. Antenna part 916a electrically connects to antenna pad 914 in proximity to conductive pillar 921 and is between conductive pillar 921 and TSV 198B. Antenna part 916b electrically connects to antenna pad 914 at the same side of the substrate as the ESD cells. Antenna part 916b is between conductive pillar 922 and TSV 198B.

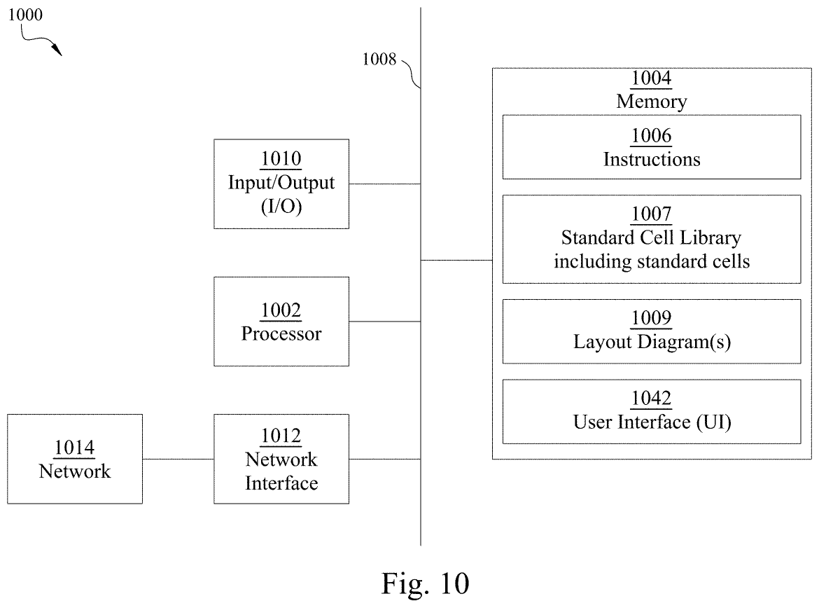

FIG. 10 is a block diagram of an electronic design automation (EDA) system 1000 in accordance with some embodiments.

In some embodiments, EDA system 1000 includes an APR system. Methods described herein of designing layout diagrams represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable storage medium 1004. Storage medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable storage medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable storage medium 1004 are capable of connecting to external elements via network 1014. Processor 1002 is configured to execute computer program code 1006 encoded in computer-readable storage medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable storage medium 1004 is an electronic, magnetic, optical, electromagnetic, infrared, and/or a semiconductor system (or apparatus or device). For example, computer-readable storage medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1004 includes a compact disk-read only memory (CD-ROM), a compact disk-read/write (CD-R/W), and/or a digital video disc (DVD).

In one or more embodiments, storage medium 1004 stores computer program code 1006 configured to cause system 1000 (where such execution represents (at least in part) the EDA tool) to be usable for performing a portion or all of the noted processes and/or methods. In one or more embodiments, storage medium 1004 also stores information which facilitates performing a portion or all of the noted processes and/or methods. In one or more embodiments, storage medium 1004 stores library 1007 of standard cells including such standard cells as disclosed herein. In one or more embodiments, storage medium 1004 stores one or more layout diagrams 1009 corresponding to one or more layouts disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

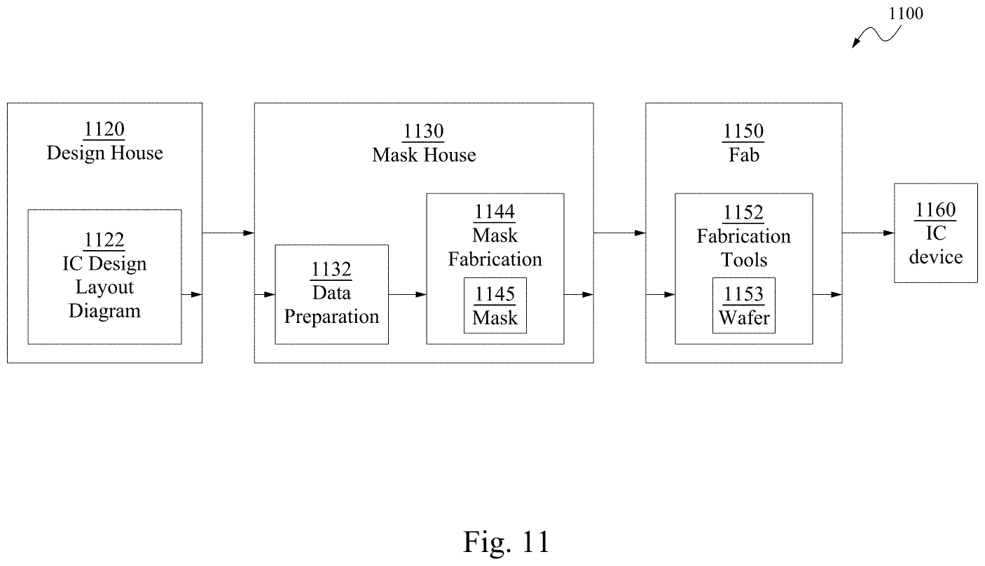

FIG. 11 is a block diagram of an integrated circuit (IC) manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122. IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

Details regarding an integrated circuit (IC) manufacturing system (e.g., system 1100 of FIG. 11), and an IC manufacturing flow associated therewith are found, e.g., in U.S. Pat. No. 9,256,709, granted Feb. 9, 2016, U.S. Pre-Grant Publication No. 20150278429, published Oct. 1, 2015, U.S. Pre-Grant Publication No. 20140040838, published Feb. 6, 2014, and U.S. Pat. No. 7,260,442, granted Aug. 21, 2007, the entireties of each of which are hereby incorporated by reference.

An aspect of the present disclosure relates to an integrated circuit. The integrated circuit includes a first keep-out zone having a first vertical zone-boundary, and a second keep-out zone having a second vertical zone-boundary. The integrated circuit also includes an array of first-type active-region structures and an array of second-type active-region structures extending in a first direction between the first vertical zone-boundary and the second vertical zone-boundary. Each of the first vertical zone-boundary and the second vertical zone-boundary extends in a second direction that is perpendicular to the first direction. The integrated circuit further includes an array of first-side boundary cells aligned with the first vertical zone-boundary along the second direction, and an array of second-side boundary cells aligned with the second vertical zone-boundary along the second direction. In the integrated circuit, a first-side boundary cell has one or more ESD protection circuits and a pick-up region, and a second-side boundary cell has one or more ESD protection circuits.

Another aspect of the present disclosure also relates to an integrated circuit. The integrated circuit includes a first keep-out zone having a first vertical zone-boundary extending in a second direction that is perpendicular to a first direction, and a second keep-out zone having a second vertical zone-boundary extending in the second direction. The integrated circuit also includes an array of active-region structures. The array of active-region structures includes a first pair of adjacent active-region structures and a second pair of adjacent active-region structures. The first pair of adjacent active-region structures has a first first-type active-region structure and a first second-type active-region structure. The second pair of adjacent active-region structures has a second first-type active-region structure and a second second-type active-region structure. The first first-type active-region structure is adjacent to the second first-type active-region structure. Each active-region structure in the array of active-region structures extends in the first direction between the first vertical zone-boundary and the second vertical zone-boundary. The integrated circuit further includes a first-side boundary cell adjacent to the first vertical zone-boundary, and a second-side boundary cell adjacent to the second vertical zone-boundary. The first-side boundary cell has one or more ESD protection circuits and at least one pick-up region. The second-side boundary cell has one or more ESD protection circuits.

Still another aspect of the present disclosure relates to a semiconductor device. The semiconductor device includes a through silicon via, a keep-out zone surrounding the through silicon via, and an active-region structure terminated at a vertical zone-boundary of the keep-out zone. The semiconductor device also includes a boundary cell having an ESD device region, a dummy device region, and a pick-up region in the active-region structure. The pick-up region is between the ESD device region and the dummy device region. The boundary cell is adjacent to the vertical zone-boundary and has an ESD protection circuit in the ESD device region.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. An integrated circuit comprising:
a first keep-out zone having a first vertical zone-boundary;
a second keep-out zone having a second vertical zone-boundary;
an array of first-type active-region structures and an array of second-type active-region structures extending in a first direction between the first vertical zone-boundary and the second vertical zone-boundary, and wherein each of the first vertical zone-boundary and the second vertical zone-boundary extends in a second direction that is perpendicular to the first direction;
an array of first-side boundary cells aligned with the first vertical zone-boundary along the second direction, wherein a first-side boundary cell has one or more ESD protection circuits and a pick-up region; and
an array of second-side boundary cells aligned with the second vertical zone-boundary along the second direction, wherein a second-side boundary cell has one or more ESD protection circuits.

2. The integrated circuit of claim 1, wherein most length of an active-region structure in the first-side boundary cell is occupied by one or more ESD device regions.

3. The integrated circuit of claim 1, wherein an active-region structure in the first-side boundary cell has an ESD device region and a dummy device region therein, and wherein the dummy device region is between the ESD device region and the first vertical zone-boundary.

4. The integrated circuit of claim 3, wherein the ESD device region is one of a diode device region or an antenna device region.

5. The integrated circuit of claim 1, wherein the pick-up region in the first-side boundary cell is an active-region structure that also has an ESD device region and a dummy device region therein, and wherein the dummy device region is between the pick-up region and the first vertical zone-boundary.

6. The integrated circuit of claim 1, wherein most length of an active-region structure in the second-side boundary cell is occupied by one or more ESD device regions.

7. The integrated circuit of claim 1, wherein an active-region structure in the second-side boundary cell has an ESD device region and a dummy device region therein, and wherein the dummy device region is between the ESD device region and the second vertical zone-boundary.

8. The integrated circuit of claim 1, wherein the second-side boundary cell further has a pick-up region.

9. An integrated circuit comprising:
a first keep-out zone having a first vertical zone-boundary extending in a second direction that is perpendicular to a first direction;
a second keep-out zone having a second vertical zone-boundary extending in the second direction;
an array of active-region structures including a first pair of adjacent active-region structures and a second pair of adjacent active-region structures, the first pair of adjacent active-region structures having a first first-type active-region structure and a first second-type active-region structure, the second pair of adjacent active-region structures having a second first-type active-region structure and a second second-type active-region structure, wherein the first first-type active-region structure is adjacent to the second first-type active-region structure, and wherein each active-region structure in the array of active-region structures extends in the first direction between the first vertical zone-boundary and the second vertical zone-boundary;
a first-side boundary cell adjacent to the first vertical zone-boundary and having one or more ESD protection circuits and at least one pick-up region; and
a second-side boundary cell adjacent to the second vertical zone-boundary and having one or more ESD protection circuits.

10. The integrated circuit of claim 9, wherein the first-side boundary cell includes a first dummy device region in the first first-type active-region structure and a second dummy device region in the first second-type active-region structure, and wherein each of the first dummy device region and the second dummy device region is adjacent to the first vertical zone-boundary.

11. The integrated circuit of claim 10, wherein the first-side boundary cell includes a first ESD device region in the first first-type active-region structure and a second ESD device region in the first second-type active-region structure.

12. The integrated circuit of claim 11, wherein the first-side boundary cell further includes a first pick-up region between the second ESD device region and the second dummy device region.

13. The integrated circuit of claim 10, wherein the first-side boundary cell includes a third dummy device region in the second first-type active-region structure and a fourth dummy device region in the second second-type active-region structure, and wherein each of the third dummy device region and the fourth dummy device region is adjacent to the first vertical zone-boundary.

14. The integrated circuit of claim 13, wherein the first-side boundary cell includes a third ESD device region in the second first-type active-region structure and a fourth ESD device region in the second second-type active-region structure.

15. The integrated circuit of claim 14, wherein the first-side boundary cell further comprises a second pick-up region between the third ESD device region and the third dummy device region.

16. The integrated circuit of claim 9, wherein the second-side boundary cell includes an ESD device region and a dummy device region in the first first-type active-region structure, and wherein the dummy device region is between the ESD device region and the second vertical zone-boundary.

17. The integrated circuit of claim 9, wherein the second-side boundary cell includes an ESD device region and a dummy device region in the first second-type active-region structure, and wherein the dummy device region is between the ESD device region and the second vertical zone-boundary.

18. The integrated circuit of claim 9, wherein the second-side boundary cell includes an ESD device region, a pick-up region, and a dummy device region in the first first-type active-region structure, and wherein the pick-up region is between the ESD device region and the dummy device region.

19. A semiconductor device comprising:
a through silicon via;
a keep-out zone surrounding the through silicon via;
an active-region structure terminated at a vertical zone-boundary of the keep-out zone;
a boundary cell having an ESD device region, a dummy device region, and a pick-up region in the active-region structure, wherein the pick-up region is between the ESD device region and the dummy device region; and
wherein the boundary cell is adjacent to the vertical zone-boundary and has an ESD protection circuit in the ESD device region.

20. The semiconductor device of claim 19, further comprising:
an antenna pad electrically connected to the ESD protection circuit.
